(19) United States
(12) Patent Application Publication
(10) Pub. No.: US 2014/0159761 A1
(43) Pub. Date: Jun. 12, 2014

(54) TEST DEVICE FOR COMPUTER INTERFACES

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventor: SONG YU, Shenzhen (CN)

(73) Assignees: HONG FU JIN PRECISION INDUSTRY (ShenZhen) CO., LTD, Shenzhen (CN); HON HAI PRECISION INDUSTRY CO., LTD., New Taipei (TW)

(21) Appl. No.: 13/756,558

(22) Filed: Feb. 1, 2013

(30) Foreign Application Priority Data
Dec. 11, 2012 (CN) 201210529736.9

(51) Int. Cl. G01R 1/04

(52) U.S. Cl. CPC G01R 1/0408
USPC 324/756.02

(57) ABSTRACT

A test device includes a circuit board with a connector, a test socket, a contact arm, and a number of signal lines. A first end of the contact arm is rotatably mounted on the circuit board and electrically connected to the test socket. A first end of the signal line is electrically connected to the connector. A second end of the signal line is fixed on the circuit board. The contact arm can be rotated to make a second end of the contact arm contact the second end of one of the signal lines.

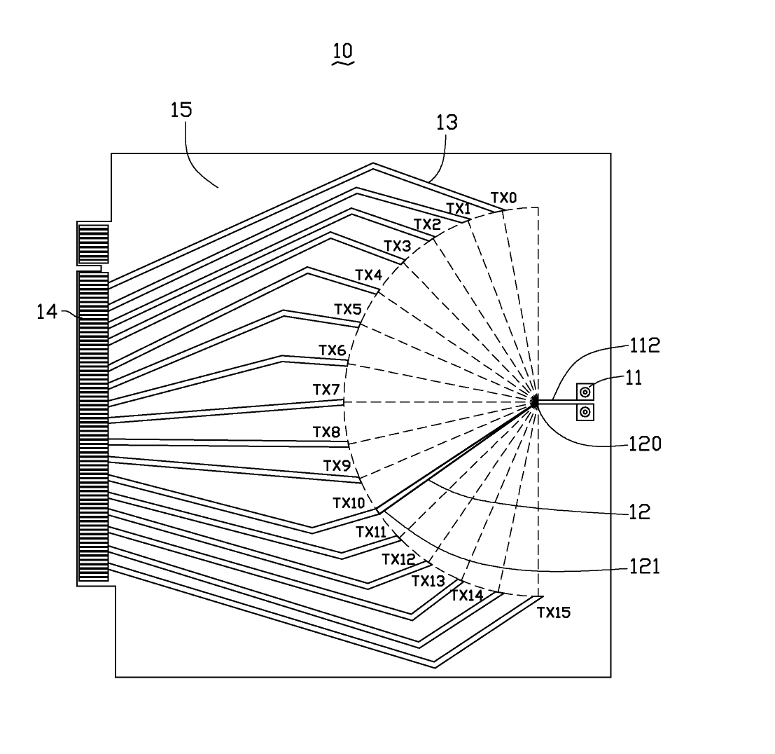

### BACKGROUND

1. Technical Field

The present disclosure relates to a device for testing interfaces.

2. Description of Related Art

With the rapid development of communication technology, computer interfaces are constantly being improved. Computer interfaces include accelerated graphics port (AGP), peripheral component interconnect interface (PCI), and peripheral component interconnect express (PCIe). The new standard interface PCIe is replacing the older PCI and AGP interfaces, because of its high transmission rate and great compatibility.

A test device for testing the PCIe interfaces includes a plurality of symmetrical multi-processing (SMP) sockets respectively corresponding to a plurality of test probes. When testing the PCIe interface, the probes are plugged into their corresponding SMP socket one at a time. Only one probe can be plugged in at any one time, a test performed, and then the plug removed before a next one is plugged in. Thus, the test is complicated and inefficient, and the probes are easily damaged due to repeatedly plugging and unplugging.

### BRIEF DESCRIPTION OF THE DRAWING

Many aspects of the embodiments can be better understood with reference to the following drawing. The components in the drawing are not necessarily drawn to scale, the emphasis instead being placed upon clearly illustrating the principles of the present embodiments. Moreover, in the drawing, like reference numerals designate corresponding parts throughout the view.

The FIGURE is a schematic, plan view of an exemplary embodiment of a test device.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean at least one.

The FIGURE shows an embodiment of a test device 10 for computer interfaces including a circuit board 15 with a test socket 11 mounted on a surface of the circuit board 15, a group of contact arms 12, an edge connector 14 formed on a side of the circuit board 15, and a plurality of groups of signal lines 13. In the embodiment, the edge connector 14 is a peripheral component interconnect express (PCIe) connector. The groups of signal lines 13 are connected to the edge connector 14. The test socket 11 is a symmetrical multi-processing (SMT) socket including two symmetrical connectors.

In the embodiment, there are two contact arms 12. Each contact arm 12 includes a connecting terminal 120 pivotably mounted on the surface of the circuit board 15 and a contact terminal 121 opposite to the connecting terminal 120. In the embodiment, the contact arm 12 is a rod made of conductive metal material, such as copper, aluminum, or iron. The connecting terminals 120 of the contact arms 12 are coaxially rotatable. Each connector of the test socket 11 is electrically connected to the connecting terminal 120 of a corresponding one of the contact arms 12 through a wire 112. The impedance of each contact arm 12 is about 50 ohms The contact arm 12 can rotate about the connecting terminal 120.

In the embodiment, the test device 10 can test 16 channel signals TX0, TX1, TX2, . . . , and TX15 received by the edge connector 14. The groups of signal lines 13 include 16 groups of signal lines. Each channel signal is transmitted by a group of signal lines 13. Each group of signal lines 13 includes two signal lines. The edge connector 14 includes 16 terminals corresponding to the 16 channel signals. First ends of each group of signal lines 13 are connected to a corresponding one of the terminals of the edge connector 14. Second ends of the signal lines 13 are fixed on the circuit board 15 and distributed along a circumference of a circle about the connecting terminals 120 of the contact arms 12. A radius of the circle is equal to the length of the contact arms 12. Therefore, the contact terminals 121 of the contact arms 12 are slidable on the circumference of the circle.

In use, the edge connector 14 is plugged into a PCIe socket set on a motherboard to be tested. The contact arms 12 are rotated and electrically contacted to the two signal lines 13 transmitting the channel signal needed to be tested, such as TX10 as shown in the FIGURE. Therefore, the two signal lines 13 are electrically connected to the test socket 11 through the contact arms 12, for transmitting the channel signal TX0 to the test socket 11. Two probes of an oscilloscope are plugged into the test socket 11. Therefore, the channel signal TX0 can be tested by observing the waveform output from the oscilloscope. When another channel signal, such as TX 11, needs to be tested, the contact arms 12 are rotated to make the contact terminals 121 contact the corresponding two signal lines 13 transmitting the channel signal TX11. During the test, the probes of the oscilloscope need not be plugged or unplugged into or from the test socket 11, which can prevent the probes from being damaged due to repeatedly plugging or unplugging, and test efficiency is improved as well.

In another embodiment, the group of contact arms 12 can include only one contact arm, and each group of signal lines 13 can include only one signal line.

The foregoing description of the exemplary embodiments of the disclosure has been presented only for the purposes of illustration and description and is not intended to be exhaustive or to limit the disclosure to the precise forms disclosed. Many modifications and variations are possible in light of disclosure above. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A test device, comprising:
a circuit board with an edge connector formed on a side of the circuit board;
a test socket mounted on a surface of the circuit board;
a contact arm comprising a connecting terminal rotatably mounted to the surface of the circuit board and electrically connected to the test socket, and a contact terminal opposite to the connecting terminal; and
a plurality of signal lines, each signal line comprising a first end electrically connected to the edge connector, and a second end fixed on the surface of the circuit board, wherein the contact arm is operable to rotate, thereby making the contact terminal of the contact arm contacts and electrically connect the second end of one of the plurality of signal lines.

2. The test device of claim 1, wherein the contact arm is a rod made of conductive material.

3. The test device of claim 2, wherein the contact arm is made of copper, aluminum, or iron.

4. The test device of claim 3, wherein impedance of the contact arm is about 50 ohms

5. The test device of claim 1, wherein the plurality of signal lines comprises 16 groups of signal lines, each group of signal lines transmits a channel signal.

6. The test device of claim 5, wherein each group of signal lines comprises two signal lines.

7. The test device of claim 6, wherein the edge connector includes 16 terminals connected to first ends of the plurality of signal lines.

8. The test device of claim 1, wherein the second ends of the plurality of signal lines are distributed along a circumference of a circle about the connecting terminal of the contact arm, a radius of the circle is equal to a length of the contact arm, the contact terminal of the contact arm is slidable on the circumference of the circle.

9. A test device, comprising:
a circuit board with a connector;
a test socket mounted on a surface of the circuit board;
a group of contact arms, each contact arm comprising a connecting terminal rotatably mounted to the surface of the circuit board and electrically connected to the test socket, and a contact terminal opposite to the connecting terminal, wherein the connecting terminals of the contact arms are coaxially rotatable; and
a plurality of groups of signal lines, each signal line comprising a first end connected to the connector, and a second end arranged on the surface of the circuit board, wherein distances from the second ends of the plurality of groups of signal lines to the connecting terminals of the contact arms are the same; and
wherein the group of contact arms are operable of rotating, thereby making the contact terminals of the group of contact arms contact the second ends of one group of signal lines.

10. The test device of claim 9, wherein the contact arms are a rod made of conductive material.

11. The test device of claim 10, wherein the contact arms are made of copper, aluminum, or iron.

12. The test device of claim 11, wherein impedance of each contact arm is about 50 ohms

13. The test device of claim 9, wherein the plurality of signal lines comprises 16 groups of signal lines, each group of signal lines transmits a channel signal received by the connector.

14. The test device of claim 13, wherein each group of signal lines comprises two signal lines, the group of contact arms comprises two contact arms, and the second end of each contact arm is operable to contact one signal line.

15. The test device of claim 13, wherein the connector includes 16 terminals connected to first ends of the plurality of signal lines.

16. The test device of claim 15, wherein the connector is a peripheral component interconnect express connector, and is formed on a side of the circuit board.
